(19) United States
(12) Patent Application Publication
(10) Pub. No.: US 2017/0271541 A1
(43) Pub. Date: Sep. 21, 2017

(54) PHOTOELECTRIC CONVERSION ELEMENT, PHOTOELECTRIC CONVERSION ELEMENT MODULE, PHOTOVOLTAIC CELL, AND PHOTOVOLTAIC POWER GENERATION SYSTEM

(71) Applicant: Kabushiki Kaisha Toshiba, Minato-ku (JP)

(72) Inventors: Miyuki SHIOKAWA, Kawasaki (JP); Naoyuki NAKAGAWA, Setagaya (JP); Hiroki HIRAGA, Saitama (JP); Soichiro SHIBASAKI, Nerima (JP); Sara YOSHIO, Taito (JP); Mutsuki YAMAZAKI, Yokohama (JP); Kazushige YAMAMOTO, Yokohama (JP)

(73) Assignee: Kabushiki Kaisha Toshiba, Minato-ku (JP)

(21) Appl. No.: 15/257,042

(22) Filed: Sep. 6, 2016

(30) Foreign Application Priority Data
Mar. 17, 2016 (JP) 2016-054556

(51) Int. Cl. H01L 31/0749; H01L 31/032; H01L 31/068

(52) U.S. Cl. CPC H01L 31/0749; H01L 31/068; H01L 31/0322; H01L 31/0687

(57) ABSTRACT

A photoelectric conversion element of an embodiment includes a first electrode, a second electrode, and a light absorbing layer, containing a chalcopyrite-type compound containing at least a group-Ib element, a group-IIIb element, and a group-VIb element, between the first electrode and the second electrode. The group-VIb element includes at least sulfur. An average sulfur atom concentration S1 in a side surface region of the light absorbing layer is higher than an average sulfur atom concentration S2 in an inside region of the light absorbing layer.

### CROSS-REFERENCE TO RELATED APPLICATION

This application is based upon and claims the benefit of priority from Japanese Patent Application No. 2016-054556, filed on Mar. 17, 2016; the entire contents of which are incorporated herein by reference.

### FIELD

Embodiments described herein relate to a photoelectric conversion element, a photoelectric conversion element module, a photovoltaic cell, and a photovoltaic power generation system.

### BACKGROUND

Development of a compound photoelectric conversion element using a semiconductor thin film as a light absorbing layer is being progressed. Among others, a photoelectric conversion element using a p-type semiconductor having a chalcopyrite structure as a light absorbing layer attracts expectation for application since the photoelectric conversion element has a high conversion efficiency and can be manufactured at relatively low cost. Specifically, a photoelectric conversion element using Cu (In, Ga) Se₂ made of Cu—In—Ga—Se (CIGS) as a light absorbing layer achieves a high conversion efficiency.

In general, a photoelectric conversion element using a p-type semiconductor made of Cu—In—Ga—Se as a light absorbing layer has a structure in which a lower electrode, a p-type semiconductor layer, an n-type semiconductor layer, an insulating layer, a transparent electrode, an upper electrode, and an antireflective film are laminated on soda-lime glass serving as a substrate. A conversion efficiency η is expressed as η=Voc·Jsc·FF/P·100, using open circuit voltage Voc, short-circuit current density Jsc, power factor FF, and incident power density P.

Generally known is a problem in which the conversion efficiency is lowered along with an increase of a light receiving area in a large-area photoelectric conversion element module in comparison with a small-area photoelectric conversion element cell. As one of causes for the decrease of the efficiency in the large-area module, degradation of the light absorbing layer occurs in a cross-section formed by means of scribing or the like for producing a serial structure. In the degraded part, leak current increases, and recombination not contributing to power generation increases, which causes the conversion efficiency to be lowered.

### BRIEF DESCRIPTION OF THE DRAWINGS

FIG. 1 is a schematic cross-sectional view of a photoelectric conversion element according to an embodiment;

FIG. 2 is a schematic cross-sectional view of a photoelectric conversion element according to the embodiment;

FIG. 3 is a schematic cross-sectional view of a multi-junction-type photoelectric conversion element according to the embodiment;

FIG. 4 is a schematic cross-sectional view of a photoelectric conversion element module according to the embodiment; and

FIG. 5 is a schematic configuration diagram of a photovoltaic power generation system according to the embodiment.

### DETAILED DESCRIPTION

A photoelectric conversion element of an embodiment includes a first electrode, a second electrode, and a light absorbing layer, containing a chalcopyrite-type compound containing at least a group-Ib element, a group-IIIb element, and a group-VIb element, between the first electrode and the second electrode. The group-VIb element includes at least sulfur. An average sulfur atom concentration S1 in a side surface region of the light absorbing layer is higher than an average sulfur atom concentration S2 in an inside region of the light absorbing layer.

Hereinbelow, an embodiment will be described in detail with reference to the drawings.

(Photoelectric Conversion Element)

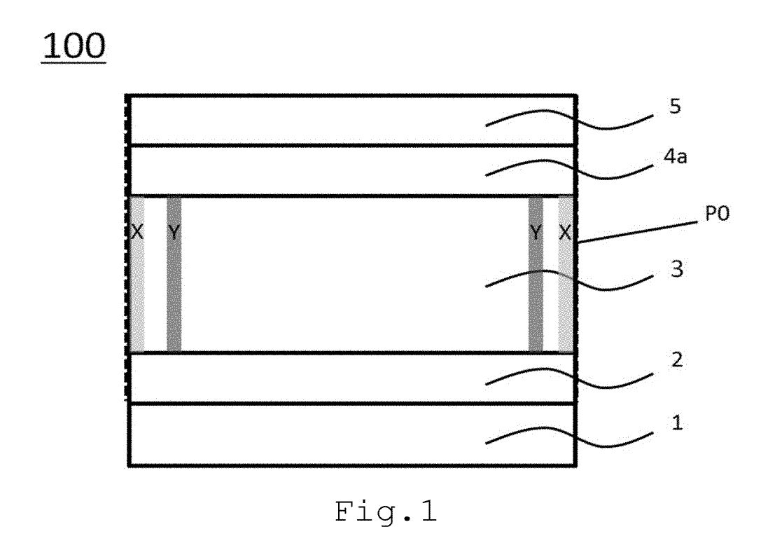

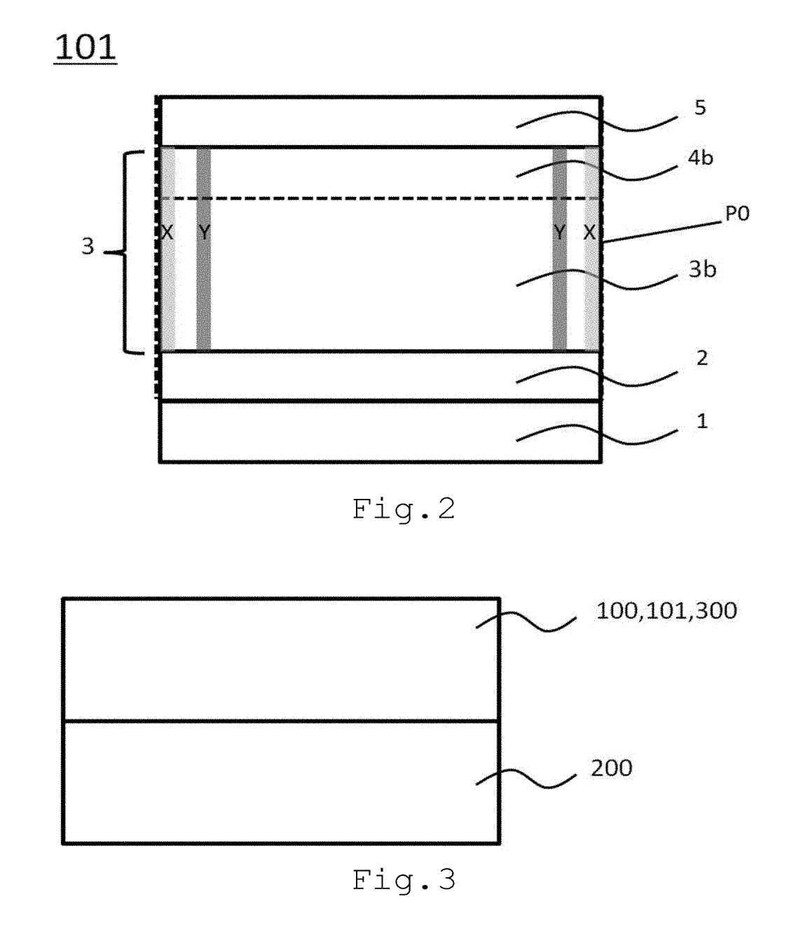

A heterojunction-type photoelectric conversion element 100 according to the present embodiment illustrated in the schematic cross-sectional view in FIG. 1 includes a substrate 1, a first electrode 2 on the substrate 1, a light absorbing layer 3 on the first electrode, an n-type compound semiconductor layer 4a on the light absorbing layer 3, and a second electrode 5 on the n-type compound semiconductor layer 4a. The light absorbing layer of the photoelectric conversion element according to the embodiment also includes a homojunction type. A homojunction-type photoelectric conversion element 101 illustrated in the schematic cross-sectional view in FIG. 2 includes the substrate 1, the first electrode 2 on the substrate 1, the light absorbing layer 3 on the first electrode, and the second electrode 5 on the light absorbing layer 3 and includes an n-type region 4b in the light absorbing layer 3 on the side of the second electrode 5.

A specific example of the photoelectric conversion element 100 is a photovoltaic cell. The photoelectric conversion element 100 or 101 according to the embodiment can be a multi-junction type when the photoelectric conversion element 100 or 101 is coupled with another photoelectric conversion element 200 as illustrated in FIG. 3. The light absorbing layer of the photoelectric conversion element 100 is preferably wider-gap than a light absorbing layer of the photoelectric conversion element 200. The light absorbing layer of the photoelectric conversion element 200 is made of Si (silicon), for example.

(Substrate)

As the substrate 1 according to the embodiment, glass containing Na (sodium) such as soda-lime glass is preferably used, and a glass kind such as quartz, white glass, and chemically strengthened glass, a metal plate made of stainless steel, Ti (titanium), Cr (chromium), or the like, or resin such as polyimide and acrylic can be used. As the substrate 1 for use in a multi-junction-type photoelectric conversion element on the top cell side, a transparent substrate is preferable.

(First Electrode)

The first electrode 2 according to the embodiment is a conductive layer on the substrate 1. The first electrode 2 is a conductive layer existing between the substrate 1 and the light absorbing layer 3. The first electrode 2 is one of electrodes of the photoelectric conversion element 100 and is a conductive metal film containing Mo, W, and the like or a semiconductor transparent conductive film containing indium-tin oxide (ITO). In a case in which the first electrode 2 is a metal film, the first electrode 2 is preferably an Mo film or a W film. In a case in which the first electrode 2 is a transparent conductive film, a layer containing oxide such as SnO₂, TiO₂, carrier-doped ZnO:Ga, and carrier-doped ZnO:Al may be laminated on a transparent conductive film ITO on the side of the light absorbing layer 3. In a case in which a semiconductor film is used as the first electrode 2, the semiconductor film may be one in which ITO and SnO₂ are laminated from the side of the substrate 1 to the side of the light absorbing layer 3 or one in which ITO, SnO₂, and TiO₂ are laminated from the side of the substrate 1 to the side of the light absorbing layer 3. Also, a layer containing oxide such as SiO₂ may further be provided between the substrate 1 and the ITO. The first electrode 2 can be formed by means of sputtering on the substrate 1. The film thickness of the first electrode 2 is 100 nm or more and 1000 nm or less, for example. The transparent conductive film used as the first electrode 2 is preferably subjected to doping at the time of film formation for improvement of characteristics. The first electrode 2 is preferably connected to a not-illustrated extraction electrode.

(Light Absorbing Layer)

The light absorbing layer 3 according to the embodiment is a compound semiconductor layer on the first electrode 2. The light absorbing layer 3 is a compound semiconductor layer existing between the first electrode 2 and the second electrode 5. The light absorbing layer 3 is a layer formed on a principal surface of the first electrode 2 on the opposite side of a surface on the side of the substrate 1. The light absorbing layer 3 is a compound semiconductor layer containing a group-Ib element, a group-IIIb element, and a group-VIb element. The group-Ib element is preferably Cu, Ag, or Cu and Ag, the group-IIIb element is preferably at least one elements selected from the group consisting of; Ga, Al, and In, and the group-VIb element preferably contains at least S and preferably further comprises Se, Te, or Se and Te. For example, a compound semiconductor layer having a chalcopyrite structure such as Cu (In, Ga) Se₂, CuInTe₂, CuGaSe₂, Cu (In, Al) Se₂, Cu (Al, Ga) (S, Se)₂, CuGa (S, Se)₂, and Ag (In, Ga) Se₂ can be used as the light absorbing layer 3. Among them, more preferably, the group-Ib element is Cu, Ag, or Cu and Ag, the group-IIIb element is Ga, Al, or Ga and Al, or at least one elements selected from the group consisting of; Ga, Al, and In, and the group-VIb element is Se and S. The at least one element selected from each group may be one kind of element or combination of two kinds of elements or more. The amount of In is preferably small in the group-IIIb element since the bandgap of the light absorbing layer 3 is easily adjusted to a preferable value as a multi-junction-type photoelectric conversion element on the top cell side. The film thickness of the light absorbing layer 3 is 800 nm or more and 3000 nm or less, for example. In the case of the mode in the cross-sectional view in FIG. 1, the light absorbing layer 3 is a p-type compound semiconductor layer. In the case of the mode in the cross-sectional view in FIG. 2, the light absorbing layer 3 is a compound semiconductor layer containing the n-type region 4b on the side of the second electrode 5 and containing a p-type region 3b on the side of the first electrode 2. The p-type region 3b and the n-type region 4b form a pn junction.

In a side surface P0 of the light absorbing layer 3 according to the embodiment, there exists a side surface region X, which contains more sulfur than an inside region Y of the light absorbing layer 3. The average sulfur atom concentration in the side surface region X is preferably higher than the average sulfur atom concentration in the inside region Y. The side surface region X is a region ranging from the side surface of the light absorbing layer 3 to a depth of 5 nm in a perpendicular direction to the side surface of the light absorbing layer 3. The inside region Y is a region having a width of 5 nm in a depth of 50 nm or more and 150 nm or less in the perpendicular direction to the side surface of the light absorbing layer 3. When [total number of sulfur atoms in side surface region]/[total number of atoms of group-Ib element, group-IIIb element, and group-VIb element in side surface region] is an average sulfur atom concentration S1 in the side surface region X, and [total number of sulfur atoms in inside region]/[total number of atoms of group-Ib element, group-IIIb element, and group-VIb element in inside region] is an average sulfur atom concentration S2 in the inside region Y, S1>S2 is preferably satisfied. Meanwhile, in a case in which the photoelectric conversion element is in the heterojunction type, the side surface P0 of the light absorbing layer 3 is a side surface extending in the perpendicular direction to the principal surface of the light absorbing layer 3 and not contacting the n-type compound semiconductor layer 4a. Also, in a case in which the photoelectric conversion element is in the homojunction type, the side surface P0 of the light absorbing layer 3 is a side surface extending in the perpendicular direction to the principal surface of the light absorbing layer 3 and including both the p-type region 3b and the n-type region 4b.

Also, as for S1−S2, which is a difference between S1 and S2, 0.01 atom %≦S1−S2≦10 atom % is more preferably satisfied. In a case of 0.01 atom %>S1−S2, the sulfur concentration hardly increases, which does not contribute to improvement of crystallization. Also, in a case of 10 atom %<S1−S2, the sulfur concentration is so high that crystallization is worsened, which undesirably causes the short-circuit current density to be lowered due to an increase of leak current and an increase of recombination. Thus, 0.01 atom %≦S1−S2≦10 atom % or 1 atom %≦S1−S2≦10 atom % is more preferably satisfied. Meanwhile, an example of the region having the width of 5 nm in the depth of 50 nm or more and 150 nm or less in the perpendicular direction to the side surface of the light absorbing layer 3 is a region having the width of 5 nm ranging from a depth of 100 nm in the perpendicular direction to the side surface of the light absorbing layer 3 to a depth of 105 nm in the perpendicular direction to the side surface of the light absorbing layer 3.

In this manner, in the photoelectric conversion element according to the embodiment, much sulfur exists in the side surface region X due to the following reason. In a photoelectric conversion element, after film formation, a side surface is mechanically or chemically treated, or scribed, to form a side surface in the photoelectric conversion element. In the chalcopyrite crystal, since combination of the group-VIb element is weaker than other combination, the group-VIb element is easily lost by such a mechanical or chemical treatment. For this reason, in the treated or formed side surface, the loss of the group-VIb element occurs significantly. Under such circumstances, in the embodiment, since sulfur, which is also the group-VIb element, is used to compensate for the loss of the group-VIb element in the side surface region, the average sulfur atom concentration S1 in the side surface region X is higher than the average sulfur atom concentration S2 in the inside region Y. In the light absorbing layer 3 according to the embodiment, since the quality of the crystal in the side surface region X is also high, the chalcopyrite crystal structure is high in quality over the entire region of the light absorbing layer 3. In a region whose crystal is low in quality, due to a phenomenon in which an increase of leak current and an increase of recombination of electrons and holes cause the short circuit current density to be lowered, the conversion efficiency of the photoelectric conversion element will be lowered. In the light absorbing layer 3 according to the embodiment, by restricting such an increase of leak current and an increase of recombination, the conversion efficiency of the photoelectric conversion element can be improved.

The sulfur atom concentration in the light absorbing layer 3 can be analyzed by elemental mapping for a sample including the side surface of the light absorbing layer 3. In consideration of concentration gradient of the group-VIb element in a film thickness direction of the light absorbing layer 3, the elemental mapping is performed at the center of each of four regions into which the side surface of the light absorbing layer 3 is divided in the film thickness direction of the light absorbing layer 3. The elemental mapping is performed in a depth direction perpendicular to the side surface with use of a 3D atom probe. As for elements contained in the light absorbing layer 3, elemental candidates contained therein are selected in advance with use of an scanning electron microscope-energy dispersive X-ray spectroscope (SEM-EDX), and powder made by scraping away a center portion of the light absorbing layer 3 in the film thickness direction is dissolved into an acid solution, is analyzed by means of inductively coupled plasma (ICP), and is quantified to clarify elements contained in the light absorbing layer 3. Meanwhile, the elements contained in the light absorbing layer 3 are elements with a concentration of 1 atom % or more among elements selected as candidates with use of the SEM-EDX and analyzed by means of the ICP. It is to be noted that sulfur shall be selected as an elemental candidate to be analyzed in the elemental mapping even when the concentration thereof is less than 1 atom % as a result of the ICP analysis.

As the sample for the 3D atom probe analysis, a sharp needle-like sample having a tip end diameter of 10 nm to 100 nm is prepared. The length of the needle-like sample has only to be longer than a region to be analyzed and be appropriate for the analysis. As for the needle-like sample, the side surface of the light absorbing layer 3 is first covered with resin so that the resin may exist at the tip end of the needle-like sample, and so that the length direction of the needle-like sample may extend in the perpendicular direction to the side surface of the light absorbing layer 3 from the tip end. Four needle-like samples are prepared per side surface to be measured. The centers of the four divided regions in the film thickness direction are to be included in the respective needle-like samples. Also, at least a range from the side surface of the light absorbing layer 3 to a depth of 100 nm in the perpendicular direction to the side surface of the light absorbing layer 3 is to be included in each of the needle-like samples. Meanwhile, in a case in which the side surface of the light absorbing layer 3 is embedded by resin or the like in advance, or in a case in which a conductive body such as an electrode is formed in the side surface of the light absorbing layer 3, the covering treatment by means of resin is omitted before preparing the needle-like samples. Thus, resin or the like or a conductive body exists in the tip end of each of the needle-like samples, and in each of middle regions of the needle-like samples, the side surface of the light absorbing layer 3 physically contacts the resin or the like or the conductive body.

The analysis was performed using LEAP4000X Si manufactured by AMETEK as the 3D atom probe, setting the measurement mode to Laser pulse, setting the laser power to 35 pJ, and setting the temperature of the needle-like sample to 70 K. A point having a depth from the tip end of the needle-like sample to the side surface of the light absorbing layer 3 is set to a point at which signal intensity of elements contained in the resin or the like contacting the side surface of the light absorbing layer 3 and not contained in the light absorbing layer 3 exceeds signal intensity of the group-Ib element in the light absorbing layer 3 for the first time. Here, the signal intensity represents a state of the detected element converted into atom %. In accordance with the purpose of the analysis, the analysis is performed from the side surface of the light absorbing layer 3 to a depth of 55 nm. As for a result of the 3D atom probe, an average value of results of the four needle-like samples is an analysis value.

Meanwhile, in a case in which much sulfur is contained at a center part of the light absorbing layer 3, sulfur may have been used as the group-VIb element at the time of forming the light absorbing layer 3. When the light absorbing layer 3 containing Se and S as the group-VIb element is formed in the chalcopyrite structure, Se and S have a slope distribution in the film thickness direction of the light absorbing layer 3. In the light absorbing layer 3 on the side of the first electrode 2, Se exists much, and S exists less. In the light absorbing layer 3 on the side of the second electrode 5, Se exists less, and S exists more. Thus, sulfur in the light absorbing layer 3 used at the time of film formation has a slope distribution in the film thickness direction. According to the embodiment, even in the light absorbing layer 3 in which sulfur is used at the time of film formation, the compensation with use of sulfur in the side surface region X can be evaluated by evaluating the difference of the sulfur concentration between the side surface region X and the inside region Y of the light absorbing layer 3. Meanwhile, in each of the needle-like samples, S1>S2 is preferably satisfied, and 0.01 atom %≦S1−S2≦10 atom % or 1 atom %≦S1−S2≦10 atom % is more preferably satisfied.

In the case of the homojunction-type photoelectric conversion element, in which the p-type region 3b and the n-type region 4b are included in the light absorbing layer 3 and are coupled, the aforementioned region compensated with use of sulfur exists in the light absorbing layer 3 including both the p-type region 3b and the n-type region 4b. In the case of the homojunction-type photoelectric conversion element, the aforementioned elemental mapping is performed to the light absorbing layer 3 including the n-type region 4b. On the other hand, in the case in which the light absorbing layer 3 forms the heterojunction with the n-type compound semiconductor layer 4a, the region compensated with use of sulfur exists in the light absorbing layer 3. In the case of the heterojunction-type photoelectric conversion element, the aforementioned elemental mapping is performed to the light absorbing layer 3 not including the n-type compound semiconductor layer 4a.

Next, a method for manufacturing the light absorbing layer 3 according to the embodiment will be described.

The light absorbing layer 3 according to the embodiment is a layer formed by forming a p-type semiconductor layer serving as a precursor thereof on the first electrode 2 and changing the type of a region of the p-type semiconductor layer on a side on which the n-type compound semiconductor layer 4a is to be formed into an n type. Examples of a process for forming the p-type semiconductor layer are thin film forming processes such as a vapor deposition process such as a three-stage process, a selenization and sulfurization process, and a sputter process. In the three-stage process according to the embodiment, Ga or In and Se or S are deposited on the first electrode 2, Cu and Se are then deposited at high temperature, and Ga or In and Se or S are thereafter deposited again, to form the light absorbing layer 3. In the selenization and sulfurization process according to the embodiment, a precursor layer containing Cu and Ga or In and Se is heated at high temperature on the first electrode 2, and surface sulfurization is thereafter performed in H₂S gas, to form the light absorbing layer 3. Methods for forming the light absorbing layer 3 according to the embodiment in the vapor deposition process and the selenization and sulfurization process will be described below.

In the vapor deposition process (three-stage process), a substrate (a member in which the first electrode 2 is formed on the substrate 1) is first heated at a temperature of 200° C. or higher and 400° C. or lower, and the group-IIIb element such as In and Ga and the group-VIb element such as Se are deposited on the substrate (first stage).

Subsequently, the substrate is heated at a temperature of 450° C. or higher and 550° C. or lower, and Cu as the group-Ib element and the group-VIb element such as Se are deposited. Start of an endothermic reaction is confirmed, and deposition of Cu as the group-Ib element is stopped with a composition in which Cu as the group-Ib element is excessive (second stage).

After the end of the second stage, the group-IIIb element such as In and Ga and the group-VIb element such as Se are deposited again (third stage) to bring the composition in slight excess of the group-IIIb element such as In and Ga.

After the end of the third stage, the substrate is irradiated with Se and is annealed while the temperature of the substrate is kept at 300° C. or higher and 550° C. or lower. A period of time for annealing is preferably 0 minutes or longer and 60 minutes or shorter (post annealing). The post annealing treatment enhances uniformity of the composition of the light absorbing layer 3 and improves crystallization of the light absorbing layer 3.

In the selenization and sulfurization process, an alloy of Ga or the like as the group-IIIb element and Cu or the like as the group-Ib element is first deposited on the first electrode 2 deposited on the substrate 1 by means of a sputter process, the group-IIIb element such as In is deposited by means of a sputter process as needed, and the group-VIb element such as Se is then deposited in a vapor deposition process (precursor layer).

The precursor layer is heated at a temperature of 450° C. or higher and 550° C. or lower to form a chalcopyrite-structured compound semiconductor containing the group-Ib element, the group-IIIb element, and the group-VIb element.

The compound semiconductor layer is subject to surface sulfurization by introducing H₂S gas diluted by, e.g., about 10% at a temperature of 450° C. or higher and 550° C. or lower, and CuGa (Se, S)₂, Cu (In, Ga) (Se, S)₂, or the like is formed on the surface, to obtain the light absorbing layer 3.

The light absorbing layer 3 formed in the selenization and sulfurization process has concentration gradient of Se and S from the part above the first electrode 2 toward the surface of the light absorbing layer 3, and formation of the light absorbing layer 3 containing uniform Se and S is impossible.

In the case in which the light absorbing layer 3 is in the homojunction type as in the mode in the cross-sectional view in FIG. 2, the type of a part of the light absorbing layer 3 is changed to an n type to form the n-type region 4b. As a method for the change to the n type, a method for doping n dopant onto the light absorbing layer 3 on the opposite side of the side of the first electrode 2 is raised. Examples of the doping method are a dip-coating method, a spray method, a spin-coating method, and a vapor method. In the dip-coating method, for example, the principal surface of the light absorbing layer 3 on the opposite side of the side of the substrate 1 is dipped into a solution at 10° C. or higher and 90° C. or lower containing Cd (cadmium), Zn (zinc), and any of Mg, Ca, and the like (e.g., a sulfate aqueous solution), serving as n dopant, and the solution is stirred for about 25 minutes. Preferably, the treated member is taken out of the solution, is washed with water on the surface thereof, and is dried. The conductivity type of a region with no change to the n type retains the p type, and this region is the p-type region 3b.

(Sulfurization Treatment)

To raise sulfur concentration of the side surface region X of the light absorbing layer 3, a sulfurization treatment is performed to the side surface P0. After the photoelectric conversion element 100 or 101 is manufactured, the side surface of the photoelectric conversion element 100 or 101 is mechanically or chemically treated, and the sulfurization treatment is performed to the mechanically-treated or chemically-treated side surface of the light absorbing layer 3. For example, in the sulfurization treatment, after at least the light absorbing layer 3 of the photoelectric conversion element 100 or 101 is dipped into a solution, such as an ammonium sulfide solution and a thioacetamide solution, having in water a compound containing 1 atom % to 50 atom % S (sulfur), or after at least the light absorbing layer 3 of the photoelectric conversion element 100 or 101 is brought into contact with gas such as hydrogen sulfide gas, the member is heated at 100° C. or higher and 350° C. or lower. The surface of the member dipped into the solution may be washed with water and dried, or may be dried by means of air drying. When the side surface of the photoelectric conversion element 100 or 101 is mechanically or chemically treated, the side surface P0 of the light absorbing layer 3 is easily oxidized. Since the oxidation of the light absorbing layer 3 causes lowering of the conversion efficiency, it is preferable to perform the sulfurization treatment immediately after the mechanical or chemical treatment.

(n-Type Compound Semiconductor Layer)

The n-type compound semiconductor layer 4a according to the embodiment is a compound semiconductor layer on the light absorbing layer 3. The n-type compound semiconductor layer 4a is a compound semiconductor layer existing between the light absorbing layer 3 and the second electrode 5. The n-type compound semiconductor layer 4a is a layer formed on the principal surface of the light absorbing layer 3 on the opposite side of the side of the first electrode 2. The n-type compound semiconductor layer 4a is a layer in heterojunction with the light absorbing layer 3. Meanwhile, in the case in which the light absorbing layer 3 is in the homojunction type, the n-type compound semiconductor layer 4a is omitted. The n-type compound semiconductor layer 4a is preferably an n-type semiconductor in which the Fermi level is controlled so that the photoelectric conversion element with high open circuit voltage can be obtained. Examples of the n-type compound semiconductor layer 4a that can be used are Zn_{1-y}Mg_{y}O₁₋ₓSₓ, Zn_{1-y-z}Mg_{z}M_{y}O, ZnO₁₋ₓSₓ, Zn_{1-z}Mg_{z}O (M is at least one element selected from the group consisting of; B, Al, In, and Ga, CdS, and n-type GaP in which carrier concentration is controlled. The at least one element of M selected from the group may be one kind of element or combination of two kinds of elements or more. The thickness of the n-type compound semiconductor layer 4a is preferably 2 nm or more and 800 nm or less. The n-type compound semiconductor layer 4a is formed by means of sputtering or CBD (chemical bath deposition), for example. In a case in which the n-type compound semiconductor layer 4a is formed by means of the CBD, the n-type compound semiconductor layer 4a can be formed on the light absorbing layer 3 by a chemical reaction of metal salt (e.g., CdSO₄), sulfide (thiourea), and a complexing agent (ammonia) in an aqueous solution. In a case in which a chalcopyrite-type compound not containing In as the group-IIIb element, such as a CuGaSe₂ layer, an AgGaSe₂ layer, a CuGaAlSe layer, and a CuGa (Se, S)₂ layer, is used for the light absorbing layer 3, the n-type compound semiconductor layer 4a is preferably CdS.

(Oxide Layer)

An oxide layer according to the embodiment is a thin film preferably provided between the n-type compound semiconductor layer 4a and the second electrode 5 or between the light absorbing layer 3 and the second electrode 5. The oxide layer may have a laminated structure. The oxide layer is a thin film containing any compound among Zn₁₋ₓMgₓO, ZnO_{1-y}S_{y}, and Zn₁₋ₓMgₓO_{1-y}S_{y} (0≦x, y<1). The oxide layer may not cover the entire principal surface of the n-type compound semiconductor layer 4a on the side of the second electrode 5. For example, the oxide layer has only to cover 50% of the surface of the n-type compound semiconductor layer 4a on the side of the second electrode 5. Other examples are wurtzite AlN, GaN, and BeO. When the volume resistivity of the oxide layer is 1 Ωcm or more, thin brings about an advantage in which leak current resulting from a low-resistance component that may exist in the light absorbing layer 3 can be restricted. It is to be noted that the oxide layer can be omitted in the embodiment.

(Second Electrode)

The second electrode 5 according to the embodiment is an electrode film that transmits light such as sunlight and that is conductive. The second electrode 5 exists on the light absorbing layer 3, on the n-type compound semiconductor layer 4a, or on the oxide layer. The second electrode 5 is formed by means of sputtering in an Ar atmosphere, for example. For the second electrode 5, ZnO:Al using a ZnO target containing 2 wt % alumina (Al₂O₃) or ZnO:B using as a dopant B from diborane or triethylboron can be used, for example.

(Third Electrode)

A third electrode according to the embodiment is an electrode of the photoelectric conversion element 100 and is a metal film formed on the second electrode 5. As the third electrode, a conductive metal film such as Ni and Al can be used. The film thickness of the third electrode is 200 nm or longer and 2000 nm or shorter, for example. In a case in which the resistance value of the second electrode 5 is low, and in which the serial resistance component is ignorable, the third electrode can be omitted.

(Antireflective Film)

An antireflective film according to the embodiment is a film to facilitate introduction of light into the light absorbing layer 3 and is formed on the second electrode 5 or on the third electrode. As the antireflective film, MgF₂ or SiO₂ is preferably used, for example. The antireflective film can be omitted in the embodiment.

(Photoelectric Conversion Element Module)

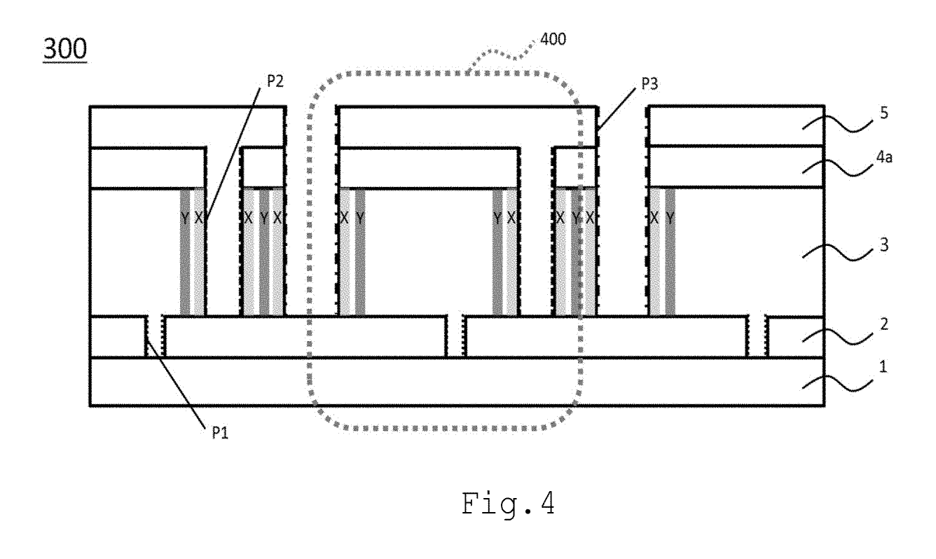

A photoelectric conversion element module 300 according to the embodiment illustrated in the schematic view in FIG. 4 is a photoelectric conversion element formed by means of patterning and cutting in a mechanical or chemical process and having side surfaces P1, P2, and P3 illustrated by dashed lines. Since electrodes, a light absorbing layer, and the like included in the photoelectric conversion element module 300 are common to those in the photoelectric conversion elements 100 and 101, description thereof will be omitted. The photoelectric conversion element module 300 can be used for a multi-junction-type photoelectric conversion element coupled with another photoelectric conversion element 200 as in FIG. 3. The photoelectric conversion element module 300 is in the heterojunction type having a structure in which unit cells 400, each of which includes the substrate 1, the first electrode 2, the light absorbing layer 3, the n-type compound semiconductor layer 4a, the second electrode 5, and the side surfaces P1, P2, and P3 circled by the dashed line in the schematic view in FIG. 4, are connected in series. The second electrode 5 in one unit cell 400 penetrates the light absorbing layer 3 and the n-type compound semiconductor layer 4a and is connected to the first electrode 2 of an adjacent unit cell to achieve serial connection between the unit cells. For the photoelectric conversion element module 300, a homojunction-type photoelectric conversion element may be used. Each unit cell 400 may include the third electrode and the antireflective film formed on the second electrode 5.

Even in a case in which the side surface region X, containing sulfur or containing much sulfur, is formed in the side surface of the light absorbing layer 3 of the module, the module structure does not need to be changed. Accordingly, forming the side surface region X is advantageous in that flexibility of design of the module structure is not reduced. For example, in a case in which the n-type compound semiconductor layer such as CdS is formed on the principal surface (upper surface) or the side surface of the light absorbing layer 3, the amount of sulfur existing in the side surface of the light absorbing layer 3 can be increased. However, in this method, since the module is mechanically or chemically cut to form the side surface, and the n-type compound semiconductor layer is thereafter formed, the n-type compound semiconductor layer will be formed on the electrode surface, which causes inter-electrode contact to be lowered. Also, flexibility of design of the module structure is reduced. In the embodiment, by increasing the amount of sulfur existing in the side surface of the light absorbing layer 3 provided with no n-type compound semiconductor layer 4a or in the side surface including the p-type region 3b and the n-type region 4b, such problems do not occur, and the quality of the light absorbing layer 3 is improved.

Hereinbelow, a method for manufacturing the photoelectric conversion element module 300 will be described. In the method for manufacturing the photoelectric conversion element module 300 according to the embodiment, the first electrode 2 formed on the substrate 1 is cut in an appropriate pattern 1 to form the side surface P1. Subsequently, the light absorbing layer 3 is formed on the first electrode 2 including the side surface P1. This causes the surface of the side surface P1 to be covered with the light absorbing layer 3. The light absorbing layer 3 is formed by means of a vapor deposition process or a sputter process. Subsequently, the n-type compound semiconductor layer 4a is formed, and the light absorbing layer 3 and the n-type compound semiconductor layer 4a are cut in an appropriate pattern 2 to form the side surface P2. Meanwhile, in the case in which the light absorbing layer 3 is in the homojunction type, after the light absorbing layer 3 is formed, the light absorbing layer 3 is cut in the appropriate pattern 2 to form the side surface P2. Subsequently, the second electrode 5 is formed on the light absorbing layer 3 and the n-type compound semiconductor layer 4a including the side surface P2. This causes the surface of the side surface P2 to be covered with the second electrode 5. Subsequently, the light absorbing layer 3, the n-type compound semiconductor layer 4a, and the second electrode 5 are cut in an appropriate pattern 3 to form the side surface P3. Subsequently, the third electrode is provided at the upper portion of the module. The antireflective film may be formed on the second electrode 5 or on the third electrode. The sulfurization treatment for the side surface P2 is performed after the side surface P2 is formed by means of scribing and before the second electrode 5 is formed. The sulfurization treatment for the side surface P3 is performed after the side surface P3 is formed by means of scribing and before resin embedding is performed.

The side surface P2, the side surface P3, or the side surfaces P2 and P3, of the photoelectric conversion element module 300 is/are subject to the sulfurization treatment, and the sulfur concentration(s) in the side surface P2, the side surface P3, or the side surfaces P2 and P3, of the light absorbing layer 3 is/are raised in a similar manner to that in the photoelectric conversion element 100 or 101. The sulfur atom concentrations in the side surface region X and the inside region Y of the photoelectric conversion element module 300 are preferably common to those in the photoelectric conversion element 100 or 101, and the aforementioned relationship between S1 and S2 is preferably satisfied in the side surface P2, the side surface P3, or the side surfaces P2 and P3, of the light absorbing layer 3. Meanwhile, although one inside region Y between the side surfaces P2 and P3 is illustrated in the figure, two inside regions Y can be provided in positions within the above-defined range in accordance with the size of the photoelectric conversion element module 300.

(Resin Embedding)

In the photoelectric conversion element module 300 according to the embodiment, the antireflective film and the scribed cross-section P3 are embedded by resin. Meanwhile, the resin embedding can be omitted in the embodiment.

(Photovoltaic Power Generation System)

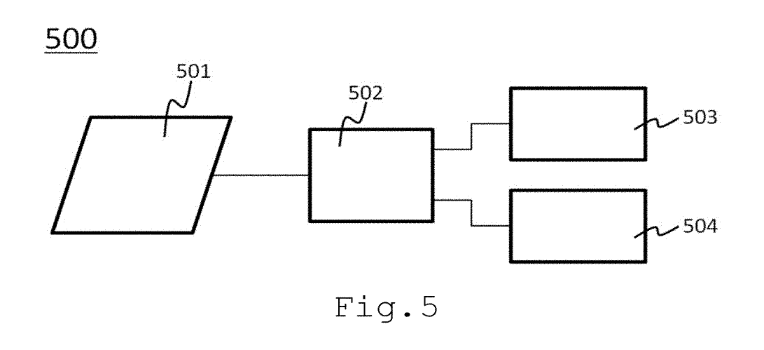

The photoelectric conversion element according to the embodiment can be used as a photovoltaic cell generating power in a photovoltaic power generation system. A photovoltaic power generation system according to the embodiment is configured to generate power with use of a photovoltaic cell and specifically includes a photovoltaic cell generating power, a means converting generated electric power, and a means storing generated electric power or a load consuming generated electric power. FIG. 5 is a schematic configuration diagram of a photovoltaic power generation system 500 according to the embodiment. The photovoltaic power generation system in FIG. 5 includes a photovoltaic cell 501, a converter 502, a battery 503, and a load 504. Either the battery 503 or the load 504 may be omitted. The load 504 may be configured to enable electric energy stored in the battery 503 to be used. The converter 502 is a device, such as a DC-DC converter, a DC-AC converter, and an AC-AC converter, including a circuit or an element performing power conversion such as transformation and conversion between DC and AC. As for a configuration of the converter 502, an appropriate configuration may be employed in accordance with voltage of generated power and configurations of the battery 503 and the load 504.

As the photovoltaic cell 501, the photoelectric conversion element described in the embodiment is preferably used. The photovoltaic cell 501 is a device including a power generating means in which the photoelectric conversion element is used alone, or in which photoelectric conversion elements are connected in series, in parallel, or in series and in parallel. The photoelectric conversion element that has received light generates electric power, and the electric energy is converted in the converter 502 and is stored in the battery 503 or is consumed in the load 504. The photovoltaic cell 501 is preferably provided with a sunlight tracking driving device configured to turn the photovoltaic cell 501 to the sun all the time, a concentrator concentrating sunlight, a device configured to improve power generation efficiency, and the like.

The photovoltaic power generation system 500 is preferably used in real estate such as houses, commercial facilities, and factories and in movable property such as vehicles, aircrafts, and electronics. By using the photoelectric conversion element according to the embodiment excellent in a conversion efficiency as the photovoltaic cell 501, an increase of the power generation amount is expected.

Hereinbelow, the embodiment will be described more specifically based on the following examples.

### Example 1

Examples will be described, using the vapor deposition process, taking as an example a method for forming a CGS layer in which the group-Ib element is Cu, the group-IIIb element is Ga, and the group-VIb element is Se. In a case of using other elements, a film can be formed similarly by using the following vapor deposition process.

On a substrate made of soda-lime glass having a width of 16 mm, a depth of 12.5 mm, and a thickness of 1.8 mm serving as the substrate 1, a laminated electrode containing respective components SnO₂ (100 nm), ITO (150 nm), and SiO₂ (10 nm) was formed by means of sputtering as the first electrode 2 so that the components may be in this order from the side of the substrate. On the first electrode 2, a CuGaSe₂ thin film serving as the light absorbing layer 3 was deposited by means of the vapor deposition process (three-stage process). The substrate was first heated at a temperature of 370° C., and Ga and Se were deposited on the substrate (first stage). Subsequently, the substrate was heated at a temperature of 500° C., and Cu and Se were deposited. Start of an endothermic reaction was confirmed, and deposition of Cu was stopped with a composition in which Cu was excessive (second stage). After the stop of the deposition, Ga and Se were deposited again (third stage) to bring the composition in slight excess of the group-IIIb element. After the end of deposition of the light absorbing layer 3, the substrate was irradiated with Se and was post-annealed for four minutes while the temperature of the substrate was kept at the temperature in the third stage. The film thickness of the light absorbing layer 3 was 1500 nm. On the p-type semiconductor layer 3 obtained as the light absorbing layer, a CdS layer serving as the n-type semiconductor layer 4a was deposited by means of solution growth. 0.002 M cadmium sulfate was added to aqueous ammonia heated at 67° C., and the member in which up to the p-type semiconductor layer 3 was deposited was dipped into the solution. After five minutes, 0.05 M thiourea was added to cause a reaction for 45 seconds. Consequently, the CdS layer having a film thickness of 10 nm was formed as the n-type semiconductor layer 4a on the p-type semiconductor layer 3. On this n-type semiconductor layer 4a, an i-ZnO thin film, which was a semi-insulating layer, was deposited as the oxide layer to about 50 nm by means of spin coating. Subsequently, an AZO thin film was deposited as the second electrode 5 to about 100 nm by means of sputtering at 100° C. Further, Al was deposited as the third electrode by means of resistance heating. The film thickness was about 300 nm. In this manner, the photoelectric conversion element 100 according to the embodiment was manufactured.

The manufactured photoelectric conversion element 100 was cut at both ends thereof by means of a scribing treatment, and the side surface P0 was formed on both the ends of the element. Subsequently, the member whose side surface was formed was dipped into an ammonium sulfide solution for 15 seconds, dried by means of air drying, and annealed in inert gas at 110° C. for five minutes, to perform the sulfurization treatment on the side surface.

In the photoelectric conversion element 100 subject to the sulfurization treatment on the side surface, open circuit voltage (Voc), short-circuit current density (Jsc), and power factor FF were measured to obtain a conversion efficiency η. Under irradiation with AM1.5 solar-simulated light of a solar simulator, with use of a voltage source and a multimeter, voltage of the voltage source was changed, and voltage generated when current under irradiation with the solar-simulated light was 0 mA was measured, to obtain the open circuit voltage (Voc). Current generated when no voltage was applied was measured to obtain the short-circuit current density (Jsc). Also, under a dark state with no light irradiation, diode current (dark current) and diode voltage were obtained.

The S atom concentration, existing in the side surface of the light absorbing layer 3 included in the side surface P0 of the photoelectric conversion element 100 subject to the sulfurization treatment on the side surface, was derived by the aforementioned method by means of the 3D atom probe analysis.

Table 1 collectively shows an elemental configuration of the photoelectric conversion element, dark current density (leak current) when the voltage is 0.6 V, short-circuit current density in a light irradiation state, an efficiency, and an average atom concentration of S atoms existing in the side surface region derived from a difference in S atoms in terms of atom % between the side surface region and the inside region by means of the 3D atom probe analysis, of each of examples and comparative examples. The dark current density, the short-circuit current density, and the efficiency are shown by relative values to those of the comparative examples. It was confirmed by the 3D atom probe analysis that the side surface of the light absorbing layer contained a region in which the S atom concentration was 0.01 atom % or more and 10 atom % or less.

### Example 2

In Example 2, film formation was performed in similar method and conditions to those of Example 1, and the photoelectric conversion element 100 and side surface P0 configured similarly were obtained. The member whose side surface was formed was dipped into an ammonium sulfide solution for 600 seconds, dried by means of air drying, and annealed in vacuum at 320° C. for 30 minutes, to perform the sulfurization treatment on the side surface.

### Comparative Examples 1 to 2

In each of Comparative Examples 1 and 2, film formation was performed in similar method and conditions to those of Examples 1 and 2, and the photoelectric conversion element 100 and side surface P0 configured similarly were obtained. In each of Comparative Examples 1 and 2, no sulfurization treatment on the side surface with use of ammonium sulfide was performed.

TABLE 1A

| | | Annealing after dipping | |
|---|---|---|---|
| | | into ammonium sulfide | |
| | Light absorbing layer | Temperature | |
| | (at time of film formation) | (° C.) | Time (minute) |
| Example 1 | CuGaSe₂ | 110 | 5 |
| Example 2 | CuGaSe₂ | 320 | 30 |
| Comparative | CuGaSe₂ | — | — |
| Example 1 | | | |
| Comparative | CuGaSe₂ | — | — |
| Example 2 | | | |

TABLE 1B

| | | | | Average sulfur |
|---|---|---|---|---|
| | | | | atom |
| | Dark | Short-circuit | | concentration |
| | current | current | Conversion | in side surface |
| | density | density | efficiency | region X |
| | (time) | (time) | (time) | (atom %) |
| Example 1 | 0.07 | 1.22 | 1.19 | 0.31 |
| Example 2 | 0.78 | 1.01 | 1.07 | 0.10 |
| Comparative | 1 | 1 | 1 | 0.00 |
| Example 1 | | | | |
| Comparative | 1 | 1 | 1 | — |
| Example 2 | | | | |

From the above examples and comparative examples, in each of the examples, S was confirmed in the side surface as a result of the 3D atom probe analysis, the leak current in the dark state was decreased further than in the comparative examples, and the short-circuit current density in the light irradiation state was increased further than in the comparative examples. Also, it is confirmed that, since the average sulfur atom concentration in the side surface region X is higher than the average sulfur atom concentration in the inside region Y in the examples, a decrease in leak current in the dark state and a decrease in recombination in the light irradiation state resulting from the increase in sulfur concentration in the side surface restrict a decrease in photo current to contribute to an increase in short-circuit current density. To further obtain the effect of increasing the short-circuit current density due to the sulfurization treatment in the side surface, the sulfur concentration in the side surface is preferably raised to some extent, and the difference in S atoms in terms of atom % is more preferably 1% or more and 10% or less. Meanwhile, in Examples 1 and 2 and Comparative Examples 1 and 2, no sulfur was detected in the inside region since the amount thereof was a detection limit or less.

The side surface sulfurization treatment is effective in that sulfurizing the entire bare side surface generally formed by scribing or etching the light absorbing layer before the side surface is damaged by oxidation and subsequent processes brings about favorable changes in photovoltaic cell characteristics. That is, it is probable that, even in a case in which the light absorbing layer contains sulfur with concentration gradient, the effect is exerted when the sulfur atom concentration in the side surface region is the sulfur atom concentration in the inside surface of the light absorbing layer or higher.

In the specification, some elements are expressed only by element symbols thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1: A photoelectric conversion element comprising:
a first electrode;
a second electrode; and
a light absorbing layer, containing a chalcopyrite-type compound containing at least a group-Ib element, a group-IIIb element, and a group-VIb element, between the first electrode and the second electrode,
wherein the group-VIb element includes at least sulfur, and
an average sulfur atom concentration S1 in a side surface region of the light absorbing layer is higher than an average sulfur atom concentration S2 in an inside region of the light absorbing layer.

2: The element according to claim 1, wherein,
in the light absorbing layer, when a region ranging from a side surface of the light absorbing layer to a depth of 5 nm in a perpendicular direction to the side surface of the light absorbing layer is the side surface region, and
in the light absorbing layer, when a region having a width of 5 nm in a depth of 50 nm or more and 150 nm or less in the perpendicular direction to the side surface of the light absorbing layer is the inside region,
[total number of sulfur atoms in the side surface region]/[total number of atoms of group-Ib element, group-IIIb element, and group-VIb element in the side surface region] is the average sulfur atom concentration S1 in the side surface region, and
[total number of sulfur atoms in the inside region]/[total number of atoms of group-Ib element, group-IIIb element, and group-VIb element in the inside region] is the average sulfur atom concentration S2 in the inside region.

3: The element according to claim 1, wherein the S1 and the S2 satisfy relationship of 0.01 atom %≦S1−S2≦10 atom %.

4: The element according to claim 1, wherein the S1 and the S2 satisfy relationship of 1 atom %≦S1−S2≦10 atom %.

5: The element according to claim 1, wherein the group-Ib element is Cu, Ag, or Cu and Ag,
the group-IIIb element is at least one element selected from the group consisting of; Ga, Al, and In, and
the group-VIb element is Se and S.

6: An element using the photoelectric conversion element according to claim 1 as a multi-junction-type photoelectric conversion element.

7: A photoelectric conversion element module using the photoelectric conversion element according to claim 1.

8: A photovoltaic cell using the photoelectric conversion element according to claim 1.

9: A photovoltaic power generation system generating power with use of the photovoltaic cell according to claim 8.

10: A photovoltaic cell using the photoelectric conversion element module according to claim 7.

11: A photovoltaic power generation system generating power with use of the photovoltaic cell according to claim 10.
